(19) United States
(12) Patent Application Publication
(10) Pub. No.: US 2026/0143659 A1
(43) Pub. Date: May 21, 2026

(54) DEVICE AND METHOD FOR ANALYZING CAUSE OF COMPONENT DISCARDING OF COMPONENT MOUNTER

(71) Applicant: HANWHA PRECISION MACHINERY CO., LTD., Changwon-si (KR)

(72) Inventors: Hyun Jin BANG, Changwon-si (KR); Jeong Pil SEO, Changwon-si (KR); Min Seok HWANG, Changwon-si (KR)

(73) Assignee: HANWHA PRECISION MACHINERY CO., LTD., Changwon-si (KR)

(21) Appl. No.: 18/706,183

(22) PCT Filed: Nov. 28, 2022
(86) PCT No.: PCT/KR2022/018914

§ 371 Date: Apr. 30, 2024

(30) Foreign Application Priority Data
Nov. 29, 2021 (KR) 10-2021-0167601

(51) Int. Cl. H05K 13/08; G01M 99/00; H05K 3/303

(52) U.S. Cl. CPC H05K 13/083; G01M 99/005; H05K 3/303

(57) ABSTRACT

The present disclosure relates to an analysis apparatus for analyzing a cause of component discarding in a component mounter. According to the present disclosure, the analysis apparatus includes an input unit configured to receive, from a user, a search condition regarding a time of occurrence of a component discarding operation, an analysis unit configured to determine, based on the search condition, a user interface (UI) screen that displays component discarding information corresponding to each of a plurality of devices that perform the component discarding operation, and a display unit configured to display the UI screen, wherein the UI screen includes a screen displaying a connection relationship between the plurality of devices and a component loss amount corresponding to each of the plurality of devices.

### TECHNICAL FIELD

The present disclosure generally relates to a method of monitoring the operation of component mounting in a surface mount technology (SMT) line, and more particularly, to an apparatus and method of analyzing the cause of component discarding by using connection information between a plurality of devices, which perform a component discarding operation, and component discarding information.

### BACKGROUND

Surface mount technology (SMT) refers to technology for mounting surface mounted components (SMCs) on the surface of a printed circuit board (PCB). Mounting systems refer to systems that produce PCB circuits by using the SMT.

Component mounters refer to equipment that performs the task of mounting electronic components, such as integrated circuits and diodes, on a PCB, and production lines refer to work lines that consist of component mounters and produce PCBs. Each of the component mounters includes a head, a nozzle, and slots for component supply and performs a mounting operation by selectively using them using a mounting program.

In the process of mounting a component on a PCB, the component mounter performs the task of lifting the component by adsorbing the component with the nozzle connected to the head. In addition, the component mounter inspects the component and then installs the component at a mounting location. However, during the process of mounting a component, there may be cases where the component mounter incorrectly adsorbs the component or cases where an abnormality is found during a component inspection process even if the component is correctly adsorbed. In this case, the component mounter discards faulty components into a discard box.

According to the related art, an analysis apparatus is used to determine the cause of component discarding in a component mounter. The analysis apparatus analyzes the cause of a component discarding operation by using individual component discarding information generated from each of a plurality of devices. That is, the analysis apparatus checks the status of component discarding corresponding to each of a plurality of devices, such as heads, nozzles, and slots. However, the analysis apparatus may not determine the connection relationship between the plurality of devices, and as a result, it is difficult to trace the cause of the component discarding operation.

The aforementioned technology is technical information possessed by the inventor for derivation of the present disclosure or acquired by the inventor during the derivation of the present disclosure, and is not necessarily prior art disclosed to the public before the application of the present disclosure.

### DESCRIPTION OF EMBODIMENTS

### Technical Problems

Based on the descriptions given above, the present disclosure provides an apparatus and method of tracking the cause of a component discarding operation of a component mounter in a surface mount technology (SMT) line.

In addition, the present disclosure provides an apparatus and method of displaying connection information between a plurality of devices, which perform a component discarding operation, and component discarding information.

In addition, the present disclosure provides an apparatus and method of analyzing the cause of component discarding occurring in a component mounter by using connection information and component discarding information.

In addition, the present disclosure provides an apparatus and method of analyzing the cause of component discarding, determining a suspect factor, and displaying the suspect factor to a user.

### Solution to Problem

According to various embodiments of the present disclosure, an analysis apparatus for analyzing a cause of component discarding in a component mounter includes an input unit configured to receive, from a user, a search condition regarding a time of occurrence of a component discarding operation, an analysis unit configured to determine, based on the search condition, a user interface (UI) screen that displays component discarding information corresponding to each of a plurality of devices that perform the component discarding operation, and a display unit configured to display the UI screen, wherein the UI screen includes a screen displaying a connection relationship between the plurality of devices and a component loss amount corresponding to each of the plurality of devices.

According to another embodiment, the analysis apparatus may further include a pre-processing unit configured to obtain production program information of the component mounter, PCB information, information on a plurality of devices, and the component discarding information, determine a connection relationship between the plurality of devices, and structure the component discarding information based on the connection relationship, wherein the plurality of devices may include at least one of a printed circuit board (PCB), a PCB lane, a head, a nozzle, a slot, a feeder, and a component, which are used by the component mounter.

According to another embodiment, the input unit may be further configured to receive at least one of PCB barcode information, PCB lane information, model information of the component mounter, and information on a type of equipment included in the component mounter.

According to another embodiment, the analysis unit may be further configured to determine a UI screen configured to display a relationship between the plurality of devices by connecting at least two of a plurality of device icons by using the plurality of device icons corresponding to the plurality of devices and display a component loss amount corresponding to each of the plurality of devices by using a component discarding information icon corresponding to each of the plurality of devices.

According to another embodiment, the input unit may be further configured to receive additional information indicating one target device among the plurality of devices from the user while the UI screen is displayed through the display unit, and the analysis unit may be further configured to determine, based on the additional information, a UI screen that displays at least one connection device connected to the target device and a component loss amount corresponding to the target device and the at least one connection device.

According to another embodiment, the analysis unit may be further configured to determine a device most causing the component discarding operation at the time of occurrence, based on the component discarding information, and determine a UI screen that displays the device most causing the component discarding operation.

According to various embodiments of the present disclosure, a method of operating an analysis apparatus for analyzing a cause of component discarding in a component mounter includes receiving, from a user, a search condition regarding a time of occurrence of a component discarding operation, determining, based on the search condition, a UI screen that displays component discarding information corresponding to each of a plurality of devices that perform the component discarding operation, and displaying the UI screen, wherein the UI screen includes a screen displaying a connection relationship between the plurality of devices and a component loss amount corresponding to each of the plurality of devices.

According to another embodiment, the method may further include obtaining production program information of the component mounter, PCB information, information on a plurality of devices, and the component discarding information, determining a connection relationship between the plurality of devices, and structuring the component discarding information based on the connection relationship, wherein the plurality of devices may include at least one of a PCB, a PCB lane, a head, a nozzle, a slot, a feeder, and a component, which are used by the component mounter.

According to another embodiment, the method may further include receiving at least one of PCB barcode information, PCB lane information, model information of the component mounter, and information on a type of equipment included in the component mounter.

According to another embodiment, the determining of the UI screen may include determining a UI screen configured to display a relationship between the plurality of devices by connecting at least two of a plurality of device icons by using the plurality of device icons corresponding to the plurality of devices and display a component loss amount corresponding to each of the plurality of devices by using a component discarding information icon corresponding to each of the plurality of devices.

According to another embodiment, the determining of the UI screen may include receiving additional information indicating one target device among the plurality of devices from the user while the UI screen is displayed, and determining, based on the additional information, a UI screen that displays at least one connection device connected to the target device and a component loss amount corresponding to the target device and the at least one connection device.

According to another embodiment, the determining of the UI screen may include determining a device most causing the component discarding operation at the time of occurrence, based on the component discarding information, and determining a Ul screen that displays the device most causing the component discarding operation.

Various respective aspects and features of the present invention are defined in the appended claims. Combinations of the characteristics of dependent claims can be appropriately combined with the characteristics of independent claims, not just explicitly presented in the claims.

Furthermore, one or more characteristics selected from any one embodiment described in the present disclosure may be combined with one or more characteristics selected from other embodiments described in the present disclosure, and an alternative combination of the characteristics may at least partially reduce one or more technical problems discussed in the present disclosure, or technical problems discernable by a typical technician from the present disclosure, and furthermore, a particular combination or permutation of embodiment features is possible unless understood by the typical technician as being incompatible.

In any described example implementation described in the present disclosure, two or more physically separate constituent elements may be alternatively integrated into a single constituent element, if the integration is possible, and when the same function is performed by the single constituent element, the integration is possible. Reversely, the single constituent element of any embodiment described in the present disclosure may be alternatively implemented, if appropriate, as two or more separate constituent elements performing the same function.

The purpose of certain embodiments of the present invention is to at least partially solve, reduce, or remove at least one of problems and/or disadvantages related to the related art. Certain embodiments are to provide at least one of the advantages described below.

### Advantageous Effects of Disclosure

An apparatus and method according to various embodiments of the present disclosure may enable to analyze the cause of component discarding by using connection information between a plurality of devices, which perform a component discarding operation, and component discarding information.

In addition, the apparatus and method according to various embodiments of the present disclosure may enable to visualize connection information between a plurality of devices, which perform a component discarding operation, and component discarding information and to provide the information to a user.

In addition, the apparatus and method according to various embodiments of the present disclosure may enable to provide a suspect factor to the user by analyzing the cause of component discarding, which occurs in a component mounter, by using connection information and component discarding information.

In addition, the apparatus and method according to various embodiments of the present disclosure may reduce the occurrence of component discarding operations by determining and analyzing a suspect factor, thereby reducing component consumption costs of a surface mount technology (SMT) line and increasing operating efficiency.

Effects that may be obtained from the present disclosure are not limited to the effects mentioned above, and other effects not mentioned may be clearly understood by one of ordinary skill in the art from the descriptions below.

### BRIEF DESCRIPTION OF DRAWINGS

FIG. 1 illustrates a component mounting system according to various embodiments of the present disclosure.

FIG. 2 illustrates an example of a plurality of icons corresponding to a plurality of devices in a component mounting system according to various embodiments of the present disclosure.

FIG. 3 illustrates a configuration of an analysis apparatus in a component mounting system according to various embodiments of the present disclosure.

FIG. 4 illustrates an example of a UI screen centered on a head in a component mounting system according to various embodiments of the present disclosure.

FIG. 5 illustrates an example of a UI screen centered on a nozzle in a component mounting system according to various embodiments of the present disclosure.

FIG. 6 illustrates an example of a UI screen centered on a slot in a component mounting system according to various embodiments of the present disclosure.

FIG. 7 illustrates an example of a UI screen centered on a feeder in a component mounting system according to various embodiments of the present disclosure.

FIG. 8 illustrates a flowchart of a method of operating an analysis apparatus in a component mounting system according to various embodiments of the present disclosure.

### MODE OF DISCLOSURE

Terms used in the present disclosure are used only to describe a specific embodiment, and may not be intended to limit the scope of other embodiments. An expression used in the singular may encompass the expression in the plural, unless it has a clearly different meaning in the context. Terms used herein, including technical or scientific terms, may have the same meaning as commonly understood by one of ordinary skill in the art described in the present disclosure. Among terms used in the present disclosure, terms defined in a general dictionary may be interpreted as having the same or similar meanings as those in the context of the related technology, and unless explicitly defined in the present disclosure, the terms are not interpreted in ideal or excessively formal meanings. In some cases, even terms defined in the present disclosure cannot be interpreted to exclude embodiments of the present disclosure.

In various embodiments of the present disclosure described below, a hardware approach is described as an example. However, because various embodiments of the present disclosure include technology using both hardware and software, various embodiments of the present disclosure do not exclude a software-based approach.

Hereinafter, the present disclosure relates to an apparatus and method of tracking the cause of component discarding in a component mounting machine (hereinafter, referred to as a component mounter). Specifically, the present disclosure describes a technique for analyzing the cause of component discarding by using connection information between a plurality of devices, which perform a component discarding operation, and component discarding information in a component mounting system.

Hereinafter, various embodiments will be described in detail with reference to the accompanying drawings such that one of ordinary skill in the art may easily implement the present disclosure. However, the technical idea of the present disclosure may be implemented by being modified in various forms, and thus is not limited to embodiments described in the present specification. While describing embodiments of the present specification, detailed descriptions about a related well-known technology are omitted when it is determined that describing the well-known technology in detail may blur the gist of the technical idea of the present disclosure. Same reference numerals are assigned to same or similar elements, and redundant descriptions thereof are omitted.

When it is described that an element is “connected” to another element in the present specification, the element may not only be “directly connected” to the other element, but may also be “indirectly connected” to the other element with another element in between. When an element “includes” or “comprises” another element, the element may further include another element instead of excluding the other element, unless otherwise stated.

Some embodiments may be described by functional block configurations and various processing operations. Some or all of these functional blocks may be implemented by various numbers of hardware and/or software configurations that perform particular functions. For example, the functional blocks of the present disclosure may be implemented by one or more microprocessors or by circuit configurations for a certain function. The functional blocks of the present disclosure may be implemented in various programming or scripting languages. The functional blocks of the present disclosure may be implemented by algorithms executed in one or more processors. A function performed by a functional block of the present disclosure may be performed by a plurality of functional blocks, or functions performed by a plurality of functional blocks of the present disclosure may be performed by one functional block. In addition, the present disclosure may employ general techniques for electronic environment setting, signal processing, and/or data processing.

Also, in the present disclosure, the expression “greater than” or “less than” is used to determine whether a specific condition is satisfied or fulfilled, but the expression only an example and another expression “equal to or greater than” or “equal to or less than” is not excluded. A condition described to be “equal to or greater than” may be replaced by “greater than”, a condition described to be “equal to or less than” may be replaced by “less than”, and a condition described to be “equal to or greater than, and less than” may be replaced by “greater than, and equal to or less than”.

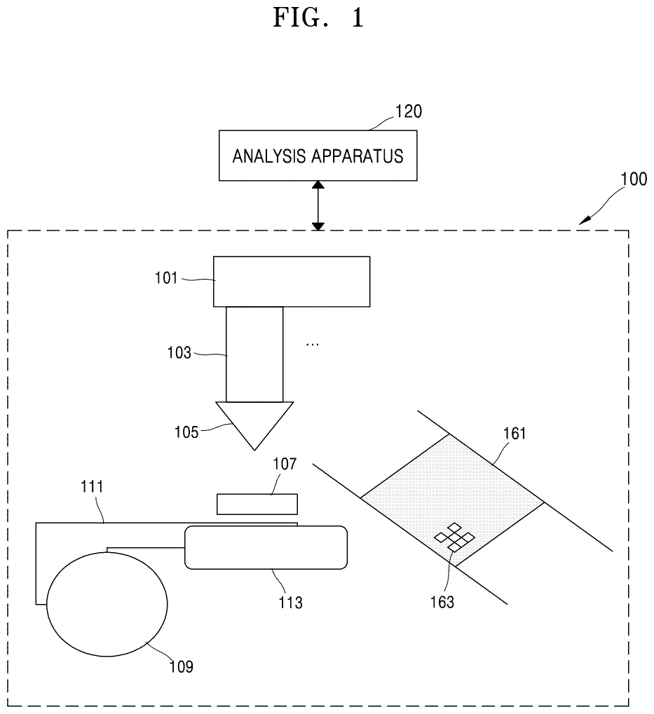

FIG. 1 illustrates a component mounting system 100 according to various embodiments of the present disclosure.

The component mounting system 100 refers to a system for mounting electronic components, such as integrated circuits and diodes, on a printed circuit board (PCB) by using a component mounter. The component mounting system 100 may include a component supply device that supplies electronic components according to control signals, and a component mounter that mounts products according to control signals from a mounting system control device.

The component supply device performs a function of supplying electronic components to the component mounter. The component supply device may perform a function of supplying electronic components, such as high-density integrated circuits, diodes, condensers, and resistors, to the component mounter. The component supply device may be referred to as a feeder 111, and the feeder 111 may supply components, such as pitch, tray, stick, and reel. Referring to FIG. 1, the component supply device may supply a component 107 in the form of a reel 109 through a slot 113 by using the feeder 111.

The component mounter performs a function of adsorbing a component at a preset location and mounting the adsorbed component on a board at another preset location. The component mounter may receive a component from the component supply device, adsorb the component, and then mount the adsorbed component at a designated location on a PCB. According to an embodiment of the present disclosure, the component mounter may include a gantry 101 for moving a component to a preset location, a head 103 for adsorbing the component and then mounting the adsorbed component on a PCB, and a nozzle 105 for receiving the component from the component supply device and adsorbing the received component.

A PCB 161 refers to a board on which components are mounted. The component mounter may create a PCB circuit by mounting components on the PCB 161 based on a designed circuit. Here, the PCB 161 may include at least one identifier to be distinguished from other PCBs. According to an embodiment of the present disclosure, the at least one identifier may include a PCB barcode 163, and a plurality of PCBs may be identified based on the PCB barcode 163.

An analysis apparatus 120 performs a function of analyzing situations that occur in the process of producing a PCB circuit. In a component mounting system, a plurality of devices discard components into a discard box when the components are incorrectly adsorbed during a component mounting process or an error occurs during a component inspection process. Here, the plurality of devices may include at least one of a PCB barcode, a PCB lane, a head, a nozzle, a slot, a component, and a feeder, which are used by the component mounter. The plurality of devices may cause component discarding operations when components are mounted differently from a pre-designed circuit. Here, the analysis apparatus 120 may perform a function of checking whether a plurality of devices used in the process of producing a PCB circuit are operating normally or whether an error has occurred and analyzing a checked result.

According to an embodiment of the present disclosure, the analysis apparatus 120 may check whether a component discarding operation is performed in each of a plurality of devices and collect data regarding the component discarding operation of each of the plurality of devices. Thereafter, the analysis apparatus 120 may track the cause of component discarding by using the data regarding the component discarding operation and provide information regarding the cause of component discarding to a user.

In an SMT line, minimizing the occurrence of component discarding operations is an important manufacturing improvement activity during a mounting process, which has the effect of reducing component consumption costs and increasing operating efficiency. According to the related art, information needed to analyze the cause of component discarding is divided by a plurality of devices, making it difficult for the user to trace the cause of component discarding and take action. Knowing connection information between a plurality of devices makes it possible to trace the cause of component discarding, and connection information within a system and PCB lot/model information has to be linked to each other and visible together to be easily used to trace the cause of component discarding. The analysis apparatus 120 according to the present disclosure may analyze abnormalities in the component mounter by using component discarding information generated from the component mounter itself. That is, the analysis apparatus 120 may provide the user with a user interface (UI) and analysis results, which visualize the relationship between factors causing component discarding so that the relationship may be easily analyzed.

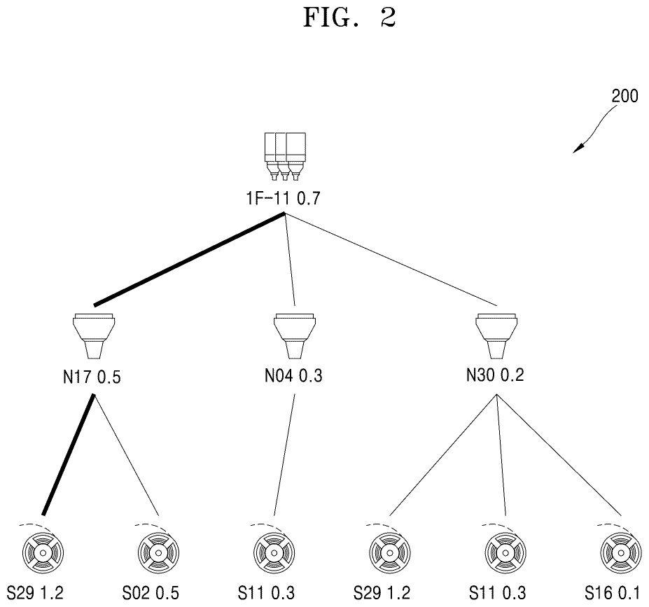

FIG. 2 illustrates an example 200 of a plurality of icons corresponding to a plurality of devices in the component mounting system 100 according to various embodiments of the present disclosure. FIG. 2 illustrates a UI screen displayed on a display screen of the analysis apparatus 120.

Referring to FIG. 2, icons related to a head, nozzle, and slot that perform a component discarding operation are illustrated. In the case where one head is selected by the user on the display screen, identification symbol icons of a selected head, nozzles used by the selected head, and components supply slots used by the nozzles are shown. Here, component codes may be displayed under the identification symbol icons of the component supply slots.

The head, nozzle, and slot may each perform a component discarding operation. Here, a component loss rate may be determined based on the number of component discarding operations of the analysis apparatus 120 in each of the head, nozzle, and slot. According to an embodiment of the present disclosure, the component loss rate of a head 1F-11 may be determined to be 0.7, the component loss rates of nozzles N17, N04, and N30 may be determined to be 0.5, 0.3, and 0.5, respectively, and the component loss rates of slots S29, S02, S11, S29, S11, and S16 may be determined to be 1.2, 0.5, 0.3, 1.2, 0.3, and 0.1, respectively. Additionally, the display screen may highlight a component having the highest component loss rate. Referring to FIG. 2, the analysis apparatus 120 may confirm that the component loss rate of each of the head 1F-11, the nozzle N17, and the slot S29 is the highest, and may emphasize devices having the highest component loss rate by displaying them in bold. The user may intuitively check head-related nozzles, component supply slots, component information, and component loss information through the display screen.

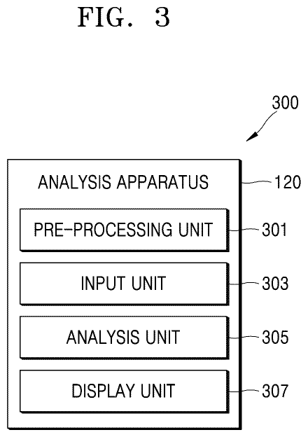

FIG. 3 illustrates a configuration 300 of the analysis apparatus 120 in the component mounting system 100 according to various embodiments of the present disclosure. Terms such as “unit” and “-er/or” described below denote a unit that processes at least one function or operation, which may be implemented in hardware or software, or implemented in a combination of hardware and software.

The analysis apparatus 120 performs a function of analyzing the cause of component discarding occurring in the component mounting system 100. In the component mounting system 100, the plurality of devices may include at least one of a PCB barcode, a PCB lane, a head, a nozzle, a slot, a component, and a feeder, which are used by the component mounter. The plurality of devices may each cause a component discarding operation when an error is detected. The analysis apparatus 120 may check the number of component discarding operations for each of the plurality of devices. According to an embodiment of the present disclosure, the analysis apparatus 120 may obtain data on a component discarding operation occurring in each of a plurality of devices over time. Thereafter, the analysis apparatus 120 may structure and store the obtained data. Thereafter, when the user inputs visual information, component discarding information corresponding to the visual information may be analyzed and analysis results may be displayed. According to an embodiment of the present disclosure, the analysis apparatus 120 may include a pre-processing unit 301, an input unit 303, an analysis unit 305, and a display unit 307.

The pre-processing unit 301 determines a connection relationship between a plurality of devices and performs a function of structuring component discarding information based on the connection relationship. The pre-processing unit 301 may structure and store data regarding the component discarding information.

According to an embodiment of the present disclosure, the pre-processing unit 301 may obtain production program information of the component mounter, PCB information, information on a plurality of devices, and component discarding information corresponding to each of the plurality of devices at a plurality of times. According to an embodiment of the present disclosure, the pre-processing unit 301 may determine a connection relationship between a plurality of devices by using production program information, a PCB barcode, a PCB lane, and information about the plurality of devices. In addition, the pre-processing unit 301 may obtain component discarding information corresponding to each of the plurality of devices at preset intervals and structure and store data to correspond to each of the plurality of devices connected according to the connection relationship.

The input unit 303 performs a function of receiving search conditions from the user. The input unit 303 may receive a search condition desired by the user in order to provide the user with the degree of component discarding for each of the plurality of devices. According to an embodiment of the present disclosure, the input unit 303 may receive a search condition regarding a time of occurrence of the component discarding operation from the user. According to another embodiment of the present disclosure, the input unit 303 may further receive at least one of PCB barcode information, PCB lane information, model information of the component mounter, and information on the type of equipment included in the component mounter.

The analysis unit 305 performs a function of determining a display screen that displays the connection relationship between the plurality of devices and the amount of component loss corresponding to each of the plurality of devices. The analysis unit 305 may analyze the cause of component discarding based on pre-stored structured data and a search condition input from the user. Based on the component discarding information, the analysis unit 305 may determine a device most causing the component discarding operation in the search condition and track the device most causing the component discarding operation. Thereafter, the analysis unit 305 may perform a function of determining a UI screen that indicates an analysis result. The UI screen may include a screen displaying the connection relationship between a plurality of devices and the amount of component loss corresponding to each of the plurality of devices.

The analysis unit 305 may display the amount of component loss between a plurality of devices and determine a UI screen that displays which factor significantly influenced the occurrence of the component discarding operation. The analysis unit 305 may store in advance a plurality of devices and a probability model corresponding to the connection relationships between the devices. The analysis unit 305 may determine a suspect factor that is the main cause of the component discarding operation based on the probability model and the number of component discarding operations. According to an embodiment of the present disclosure, the analysis unit 305 may identify a device that is the main cause of component discarding by comparing, for each device, the average number of component discarding operations according to the probability model and the actual number of component discarding operations. Thereafter, the analysis unit 305 may determine a display screen that highlights and displays the device that is the main cause of component discarding, thereby providing the user with information about the suspect factor.

The display unit 307 performs a function of displaying a UI screen. The display unit 307 may display a UI screen through a display screen in order to provide the user with the UI screen determined by the analysis unit 305.

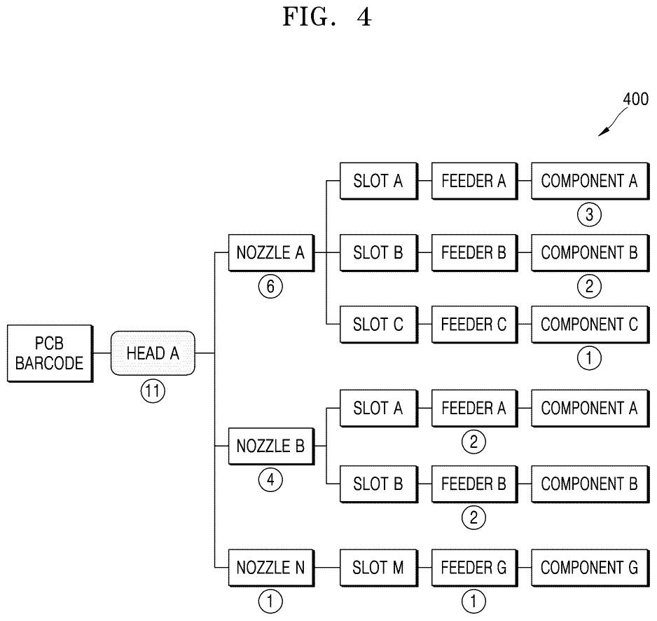

FIG. 4 illustrates an example 400 of a UI screen centered on a head in the component mounting system 100 according to various embodiments of the present disclosure. FIG. 4 illustrates a UI screen determined by the analysis unit 305 when the user inputs head A through the input unit 303.

The analysis apparatus 120 may provide the user with a UI screen on which the connection relationship between a plurality of devices that generate a component discarding operation is displayed. Accordingly, the user may easily identify the phenomenon of the occurrence of component discarding from the UI screen. The UI screen may include a head, a nozzle slot, a feeder, a discarded component, a PCB job, a PCB barcode, equipment, and a PCB lane, and the connection relationship between the devices may be expressed on the UI screen. The analysis apparatus 120 allows the user to easily analysis component discarding and trace the cause of component discarding by improving the UI screen.

Referring to FIG. 4, the input unit 303 of the analysis apparatus 120 may receive a search condition regarding the occurrence time from the user. Here, the input unit 303 may additionally receive information about the devices along with the occurrence time. FIG. 4 illustrates a case where the input unit 303 receives head A as input from the user.

The analysis unit 305 of the analysis apparatus 120 may determine the connection relationship between a plurality of devices by using structured data. The analysis apparatus 120 may obtain production program information of the component mounter, PCB information, and information on a plurality of devices, and may display a plurality of devices, which interact with each other in the process of producing a PCB circuit, to be connected to each other. According to an embodiment of the present disclosure, the plurality of devices may include a PCB, a PCB lane, a head, a nozzle, a slot, a feeder, and a component, and the analysis apparatus 120 may determine the connection relationship in the order of PCB barcode-head-nozzle-slot-feeder-component.

Referring to FIG. 4, head A may perform mounting work on the PCB that is a mounting target. Head A may mount components by using nozzles A, B, and N. In the same way, nozzle A may use slots A, B, and C, nozzle B may use slots A and B, and nozzle N may use slot M. Slots A, B, C, and M may feed components A, B, C, and G through feeders A, B, C, and G, respectively. That is, when the user selects head A, a plurality of devices that interact with head A may be connected to each other in the form of a mind map or tree.

In addition, the analysis apparatus 120 may determine the number of times a component discarding operation occurs in each of the plurality of devices by using structured data. The analysis apparatus 120 may determine a UI screen, which displays the number of component discarding operations at the bottom of each device, in the UI screen that displays the connection relationship. Referring to FIG. 4, in nozzle A, the number of components A in which component discarding occurs may be 3, the number of components B in which component discarding occurs may be 2, and the number of components C in which component discarding occurs may be 1.

Accordingly, in nozzle A, the component discarding operation may occur six times. In the same way, the number of component discarding operations occurring in nozzle B may be determined to be 4, and the number of component discarding operations occurring in nozzle N may be determined to be 1. As a result, the number of component discarding operations that occur in head A may be determined to be 11.

The analysis unit 305 may determine a UI screen that displays each connection relationship regarding the mutual operation between a plurality of devices centered on the head, and the amount of component loss related to the number of component discarding operations. The analysis unit 305 may display the determined UI screen through the display unit 307.

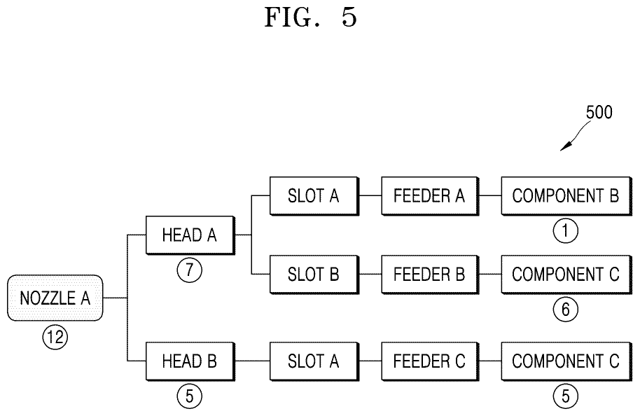

FIG. 5 illustrates an example 500 of a UI screen centered on a nozzle in the component mounting system 100 according to various embodiments of the present disclosure. FIG. 5 illustrates a UI screen determined by the analysis unit 305 when the user inputs nozzle A through the input unit 303.

The analysis apparatus 120 may obtain production program information of the component mounter, PCB information, and information on a plurality of devices, and may display a plurality of devices, which interact with each other in the process of producing a PCB circuit, to be connected to each other. According to an embodiment of the present disclosure, the analysis apparatus 120 may determine the connection relationship in the order of PCB barcode-head-nozzle-slot-feeder-component. In this case, when the user inputs a nozzle into a search condition, the analysis unit 305 may determine the connection relationship between a plurality of devices centered on the nozzle. Referring to FIG. 5, the analysis unit 305 may determine the connection relationship in the order of nozzle-head-slot-feeder-component. Although not shown in FIG. 5, the analysis unit 305 may additionally determine the connection relationship between the nozzle, the PCB barcode, and the PCB lane.

Referring to FIG. 5, nozzle A may perform mounting work on a PCB that is a mounting target. Nozzle A may be connected to heads A and B so that components may be mounted. In the same way, head A may use slots A and B, and head B may use slot B. Slots A and B may respectively receive components B and C through feeders A, B, and C. That is, when the user selects nozzle A, a plurality of devices that interact with nozzle A may be connected to each other in the form of a mind map or tree.

In addition, in the UI screen displaying the connection relationship of the analysis apparatus 120, a UI screen displaying the number of times a component discarding operation occurs in each of the plurality of devices may be determined using structured data. Referring to FIG. 5, in head A, the number of components B in which component discarding occurs may be 1, and the number of components C in which component discarding occurs may be 6 Accordingly, in head A, the component discarding operation may occur 7 times. In the same way, the number of component discarding operations occurring in head B may be determined to be 5. As a result, the number of component discarding operations that occur in nozzle A may be determined to be 11.

The analysis unit 305 may determine a UI screen that displays each connection relationship regarding the mutual operation between a plurality of devices centered on the nozzle, and the amount of component loss related to the number of component discarding operations. The analysis unit 305 may display the determined UI screen through the display unit 307.

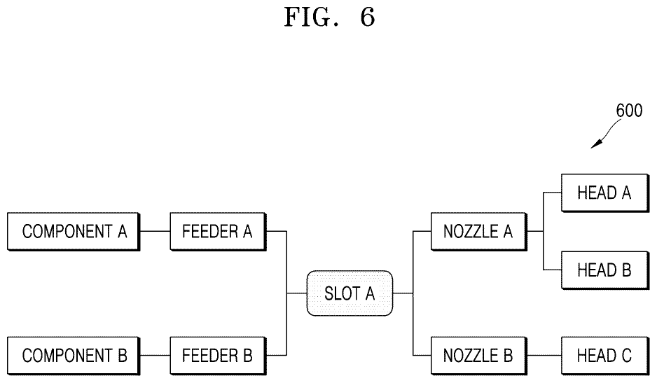

FIG. 6 illustrates an example 600 of a UI screen centered on a slot in the component mounting system 100 according to various embodiments of the present disclosure. FIG. 6 illustrates a UI screen determined by the analysis unit 305 when the user inputs slot A through the input unit 303.

The analysis apparatus 120 may obtain production program information of the component mounter, PCB information, and information on a plurality of devices, and may display a plurality of devices, which interact with each other in the process of producing a PCB circuit, to be connected to each other. According to an embodiment of the present disclosure, the analysis apparatus 120 may determine the connection relationship in the order of PCB barcode-head-nozzle-slot-feeder-component. In this case, when the user inputs a slot into a search condition, the analysis unit 305 may determine the connection relationship between a plurality of devices centered on the slot.

Referring to FIG. 6, mounting work may be performed through slot A. Slot A may be connected to nozzles A and B so that components may be mounted. Nozzle A may be connected to heads A and B, and nozzle B may be connected to head C. Slot A may receive components A and B through feeders A and B. That is, when the user selects slot A, a plurality of devices that interact with slot A may be connected to each other in the form of a mind map or tree.

The analysis unit 305 may determine a UI screen that displays each connection relationship regarding the mutual operation between a plurality of devices centered on the nozzle, and the amount of component loss related to the number of component discarding operations. The analysis unit 305 may display the determined UI screen through the display unit 307.

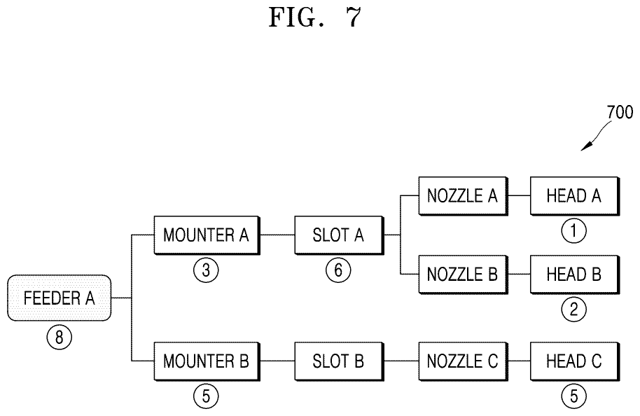

FIG. 7 illustrates an example 700 of a UI screen centered on a feeder in the component mounting system 100 according to various embodiments of the present disclosure. FIG. 7 illustrates a UI screen determined by the analysis unit 305 when the user inputs feeder A through the input unit 303.

The analysis apparatus 120 may obtain production program information of the component mounter, PCB information, and information on a plurality of devices, and may display a plurality of devices, which interact with each other in the process of producing a PCB circuit, to be connected to each other. According to an embodiment of the present disclosure, the analysis apparatus 120 may determine the connection relationship in the order of PCB barcode-head-nozzle-slot-feeder-component. In this case, when the user inputs a feeder into a search condition, the analysis unit 305 may determine the connection relationship between a plurality of devices centered on the feeder. Referring to FIG. 7, the analysis unit 305 may determine the connection relationship in the order of feeder-mounter-slot-nozzle-head.

Referring to FIG. 7, feeder A may supply components to mounters A and B. Mounter A may use heads A and B and nozzles A and B and may perform mounting work through slot A. In the same way, mounter B may use head C and nozzle C and perform mounting work through slot B. That is, when the user selects feeder A, a plurality of devices that interact with feeder A may be connected to each other in the form of a mind map or tree.

In addition, in the UI screen displaying the connection relationship of the analysis apparatus 120, a UI screen displaying the number of times a component discarding operation occurs in each of the plurality of devices may be determined using structured data. Referring to FIG. 7, the number of times component discarding occurs in head A may be 1, and the number of times component discarding occurs in head B may be 2. Accordingly, in mounter A, the component discarding operation may occur three times. In the same way, the number of component discarding operations occurring in mounter B may be determined to be 5. As a result, the number of component discarding operations that occur in feeder A may be determined to be 12.

The analysis unit 305 may determine a UI screen that displays each connection relationship regarding the mutual operation between a plurality of devices centered on the feeder, and the amount of component loss related to the number of component discarding operations. The analysis unit 305 may display the determined UI screen through the display unit 307.

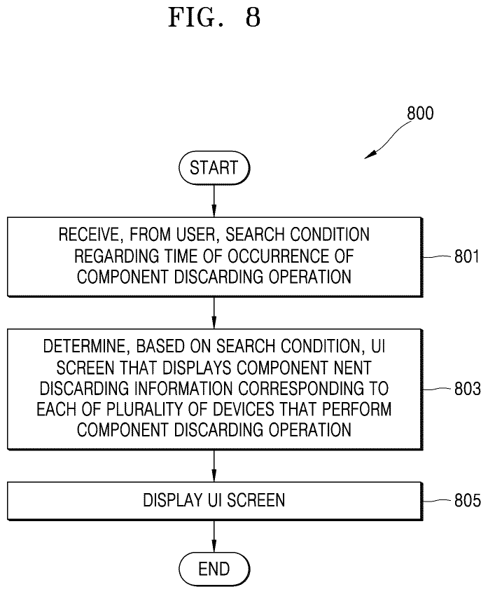

FIG. 8 illustrates a flowchart 800 of a method of operating the analysis apparatus 120 in the component mounting system 100 according to various embodiments of the present disclosure. FIG. 8 illustrates a method of operating the analysis apparatus 120 for analyzing the cause of component discarding in a component mounter.

Referring to FIG. 8, in operation 801, the analysis apparatus 120 receives, from the user, a search condition regarding a time of occurrence of a component discarding operation. The analysis apparatus 120 may receive a search condition input from the user. According to an embodiment of the present disclosure, the analysis apparatus 120 may obtain production program information of a component mounter, PCB information, information on a plurality of devices, and component discarding information at a plurality of times. In addition, the analysis apparatus 120 may determine a connection relationship between a plurality of devices and may structure and store component discarding information based on the connection relationship. According to an embodiment of the present disclosure, the plurality of devices may include at least one of a PCB, a PCB lane, a head, a nozzle, a slot, a feeder, and a component, which are used by a component mounter.

An input unit may receive additional information along with information about the time of occurrence. According to an embodiment of the present disclosure, the analysis apparatus 120 may further receive at least one of PCB barcode information, PCB lane information, model information of the component mounter, and information on the type of equipment included in the component mounter. In addition to the above information, the purpose of the present method and apparatus may be implemented by receiving additional information that may be generated and detected during the process of supplying, adsorbing, and mounting various components.

In operation 803, the analysis apparatus 120 determines, based on the search condition, a UI screen that displays component discarding information corresponding to each of the plurality of devices that perform a component discarding operation. The UI screen may include a screen displaying the connection relationship between a plurality of devices and the amount of component loss corresponding to each of the plurality of devices.

According to an embodiment of the present disclosure, the analysis apparatus 120 may determine a UI screen that displays a relationship between the plurality of devices by connecting at least two of a plurality of device icons by using the plurality of device icons corresponding to the plurality of devices and displays a component loss amount corresponding to each of the plurality of devices by using a component discarding information icon corresponding to each of the plurality of devices.

According to an embodiment of the present disclosure, the analysis apparatus 120 may receive, through the input unit 303, additional information indicating one target device among the plurality of devices from the user while the UI screen is displayed through the display unit, and may determine, through the analysis unit 305, a Ul screen, which displays at least one connection device connected to a target device and a component loss amount corresponding to the target device and the at least one connection device, based on the additional information.

According to an embodiment of the present disclosure, the analysis apparatus 120 may determine a device most causing a component discarding operation at an occurrence time based on component discarding information and may display a UI screen that displays the device most causing the component discarding operation.

In operation 805, the analysis apparatus 120 displays a UI screen. The analysis apparatus 120 may provide the user with a UI screen determined by the analysis unit 305. According to an embodiment of the present disclosure, the analysis apparatus 120 may provide a UI screen to the user through a display screen.

The methods according to the embodiments described in the claims or specification of the present disclosure may be implemented by hardware, software, or a combination of hardware and software.

When the method is implemented by software, a computer-readable storage medium having stored one or more programs (software module) therein may be provided. The one or more programs stored in the computer-readable storage medium are configured to be executed by one or more processors in an electronic device. The one or more programs may include instructions to perform, by an electronic device, the methods described in the claims or specification of the present disclosure.

The program (software module or software) may be stored in random access memory (RAM), non-volatile memory including flash memory, read only memory (ROM), electrically erasable programmable read only memory (EEPROM), magnetic disc storage devices, optical storage devices in the form of compact disc-ROMs, CD-ROMs, digital versatile discs (DVDs), or the like, and magnetic cassettes. Alternatively, the program may be stored in a memory configured with a combination of some or all thereof. Furthermore, each component memory may include a plurality of memories.

Furthermore, the programs may be stored in attachable storage devices to be accessible through a communication network, such as the Internet, Intranet, a local area network (LAN), a wide area network (WAN), a storage area network (SAN), or a combination thereof. The storage device may be connected to a device that performs an embodiment of the present disclosure through an external port. Furthermore, a separate storage device on a communication network may be connected to a device that performs an embodiment of the present disclosure.

In the specific embodiments of the present disclosure described above, a component included in the present disclosure is expressed in a singular or plural form according to the disclosed specific embodiment. However, the singular or plural expression is selected suitable for the disclosed situation, for convenience of explanation, the present disclosure is not limited to a singular or plural components, and a component expressed in a plural form may include a single component, whereas a component expressed in a singular form may include a plurality of components.

Meanwhile, in the detailed description of the present disclosure, specific embodiments have been described, but various modifications are possible without departing from the scope of the present disclosure. Therefore, the scope of the present disclosure should not be limited to the described embodiments, but should be determined not only by the scope of the claims described later, but also by equivalents to the scope of the claims.

1. An analysis apparatus for analyzing a cause of component discarding in a component mounter, the analysis apparatus comprising:
an input unit configured to receive, from a user, a search condition regarding a time of occurrence of a component discarding operation;
an analysis unit configured to determine, based on the search condition, a user interface (UI) screen that displays component discarding information corresponding to each of a plurality of devices that perform the component discarding operation; and
a display unit configured to display the UI screen,
wherein the UI screen includes a screen displaying a connection relationship between the plurality of devices and a component loss amount corresponding to each of the plurality of devices.

2. The analysis apparatus of claim 1, wherein the connection relationship between the plurality of devices includes a connection record of a plurality of devices related to a component mounting operation.

3. The analysis apparatus of claim 1, wherein the plurality of devices include at least one of a printed circuit board (PCB), a PCB lane, a head, a nozzle, a slot, a feeder, and a component, which are used by the component mounter.

4. The analysis apparatus of claim 1, further comprising a pre-processing unit configured to obtain production program information of the component mounter, PCB information, information on a plurality of devices, and the component discarding information, determine a connection relationship between the plurality of devices, and structure the component discarding information based on the connection relationship.

5. The analysis apparatus of claim 1, wherein the input unit is further configured to receive at least one of PCB barcode information, PCB lane information, model information of the component mounter, and information on a type of equipment included in the component mounter.

6. The analysis apparatus of claim 1, wherein the analysis unit is further configured to determine a UI screen configured to display a relationship between the plurality of devices by connecting at least two of a plurality of device icons by using the plurality of device icons corresponding to the plurality of devices and display a component loss amount corresponding to each of the plurality of devices by using a component discarding information icon corresponding to each of the plurality of devices.

7. The analysis apparatus of claim 6, wherein the input unit is further configured to receive additional information indicating one target device among the plurality of devices from the user while the UI screen is displayed through the display unit, and
the analysis unit is further configured to determine, based on the additional information, a UI screen that displays at least one connection device connected to the target device and a component loss amount corresponding to the target device and the at least one connection device.

8. The analysis apparatus of claim 1, wherein the analysis unit is further configured to:
determine a device most causing the component discarding operation at the time of occurrence, based on the component discarding information, and
determine a UI screen that displays the device most causing the component discarding operation.

9. A method of operating an analysis apparatus for analyzing a cause of component discarding in a component mounter, the method comprising:
receiving, from a user, a search condition regarding a time of occurrence of a component discarding operation;
determining, based on the search condition, a UI screen that displays component discarding information corresponding to each of a plurality of devices that perform the component discarding operation; and
displaying the UI screen,
wherein the UI screen includes a screen displaying a connection relationship between the plurality of devices and a component loss amount corresponding to each of the plurality of devices.

10. The method of claim 9, wherein the connection relationship between the plurality of devices includes a connection record of a plurality of devices related to a component mounting operation.

11. The method of claim 9, further comprising obtaining production program information of the component mounter, PCB information, information on a plurality of devices, and the component discarding information, determining a connection relationship between the plurality of devices, and structuring the component discarding information based on the connection relationship,
wherein the plurality of devices include at least one of a PCB, a PCB lane, a head, a nozzle, a slot, a feeder, and a component, which are used by the component mounter.

12. The method of claim 9, further comprising receiving at least one of PCB barcode information, PCB lane information, model information of the component mounter, and information on a type of equipment included in the component mounter.

13. The method of claim 9, wherein the determining of the UI screen comprises determining a UI screen configured to display a relationship between the plurality of devices by connecting at least two of a plurality of device icons by using the plurality of device icons corresponding to the plurality of devices and display a component loss amount corresponding to each of the plurality of devices by using a component discarding information icon corresponding to each of the plurality of devices.

14. The method of claim 11, wherein the determining of the UI screen comprises:
receiving additional information indicating one target device among the plurality of devices from the user while the UI screen is displayed; and
determining, based on the additional information, a UI screen that displays at least one connection device connected to the target device and a component loss amount corresponding to the target device and the at least one connection device.

15. The method of claim 9, wherein the determining of the UI screen comprises:
determining a device most causing the component discarding operation at the time of occurrence, based on the component discarding information; and
determining a UI screen that displays the device most causing the component discarding operation.
